(19) United States
(12) Patent Application Publication
(10) Pub. No.: US 2016/0170452 A1
(43) Pub. Date: Jun. 16, 2016

(54) MOBILE OFFICE COMMUNICATION SYSTEM

(71) Applicant: Birch Communications, Inc., Atlanta, GA (US)

(72) Inventors: Stephen Sigmon, Buford, GA (US); Jason Barber, Dallas, GA (US)

(21) Appl. No.: 14/959,563

(22) Filed: Dec. 4, 2015

Related U.S. Application Data
(60) Provisional application No. 62/090,111, filed on Dec. 10, 2014.

(51) Int. Cl. G06F 1/16; H05K 5/00; H01R 13/73

(52) U.S. Cl. CPC G06F 1/1698; G06F 1/1628; H01R 13/73; H05K 5/0013

(57) ABSTRACT

A mobile office communication system is provided that comprises a partial mobile wall that is mounted on wheels. An enclosure is coupled to a surface of the partial wall. The enclosure is formed from a first portion that is mounted to the partial wall and a second portion that is releasably coupled to the first portion. The mobile office communication system also contains various electronic components that are either housed in the enclosure or coupled to the partial wall to allow the user to setup mobile offices in any location. Furthermore, the system may also provide an indoor and outdoor wireless access point. The system is configured to be self-contained, mobile and provide wired and wireless portable office.

### CROSS-REFERENCE TO RELATED APPLICATIONS

This application claims the benefit of U.S. Provisional Application No. 62/090,111, filed Dec. 10, 2014, entitled “Mobile Office Communication System”, which is hereby incorporated by reference in its entirety.

### BACKGROUND

Advancements in technology have helped to virtually minimize the physical distance between two parties. Despite these technological advancements however, numerous consultants, attorneys, auditors, and other professionals find themselves being flown to a client's physical location regularly to interface with the client's representatives. Inherent in this type of work arrangement is providing the traveling professional with restricted access to parts of the client's network, while enabling the visitor to access any data and software they would have if they were working from their home office. This arrangement may present problems for the client as well as for the consultant. Where the client needs to maintain sufficient security settings and permissions within their own network, the consultant needs unfettered access to their home network, files, and applications. Additionally, the cost of an improperly configured network or the downtime that may result from time spent integrating network resources can cost companies lost man hours and lost productivity.

Various embodiments of the present system and methods recognize and address the foregoing considerations, and others, of prior art systems and methods.

### SUMMARY OF THE VARIOUS EMBODIMENTS

In various embodiments, a self-contained, portable system and method for allowing secure network configuration and connectivity on a remote site comprises: (A): a portable wall comprising: (1) a front surface, (2) a left side wall, (3) a right side wall, and (4) a back surface; (B): an enclosure mounted to one of the front and the back surface, the enclosure comprising (1) a first enclosure portion mounted to the one of the front surface and the back surface, and (2) a second enclosure portion that is releasably coupled to the first enclosure portion; (C) an electrical connector mounted to the portable wall; (D) a security appliance that is received in the enclosure; (E) an integrated services router that is received in the enclosure; and (F) at least one of a 4G wireless modem and a cable modem, wherein (1) the electrical connector is configured to operatively couple to a power source and to provide at least one electrical outlet, and (2) the security appliance, the integrated services router, and the at least one of the 4G wireless modem and the cable modem are operatively coupled to one another and to the electrical outlet.

A method of providing a mobile communication system for use with mobile offices, in various embodiments, comprises: (A) providing a portable communication system further comprising: (1) a wall having wheels, (2) an equipment enclosure, (3) an integrated services router that is configured to operatively couple to a wireless modem, (4) a security appliance that is configured to operatively couple to a wireless modem, and (5) a power connector that is configured to connect to a power source and to provide power to the integrated services router and the security appliance; (B) operatively coupling the integrated services router to the security appliance; and (C) operatively coupling the integrated services router and the security appliance to the power connector.

### BRIEF DESCRIPTION OF THE DRAWINGS

Various embodiments of systems and methods for the implementation of a mobile office communication system are described below. In the course of this description, reference will be made to the accompanying drawings, which are not necessarily drawn to scale and wherein:

FIG. 1 is a block diagram of an exemplary system for the implementation of a mobile office communication system in accordance with an embodiment of the present system;

FIG. 2 is a block diagram of a computer that may be used in the system shown in FIG. 1;

FIG. 3A is a left front perspective view of the mobile office communication system of FIG. 1 with the enclosure operatively coupled according to particular embodiments;

FIG. 3B is a right front perspective view of the mobile office communication system of FIG. 1 with the enclosure opened according to particular embodiments;

FIG. 3C is a front plan view of the mobile office communication system of FIG. 1 with the enclosure operatively coupled according to a particular embodiment;

FIG. 3D is a rear plan view of the attached mobile office communication system of FIG. 1 according to a particular embodiment;

FIG. 3E is a right side plan view of the mobile office communication system of FIG. 1 with the enclosure operatively coupled according to a particular embodiment;

FIG. 3F is a left side plan view of the mobile office communication system of FIG. 1 with the enclosure operatively coupled according to a particular embodiment;

FIG. 4 depicts a flowchart that generally illustrates the configuration and interoperability of the components of the mobile office communication system of FIG. 1 according to a particular embodiment.

### DETAILED DESCRIPTION OF SOME EMBODIMENTS

Various embodiments will now be described more fully hereinafter with reference to the accompanying drawings. It should be understood that the invention may be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

### Overview

In particular embodiments, a mobile office communication system is provided that includes a partial mobile wall that is mounted on wheels. The partial wall has a front surface, a back surface and two side surfaces. In various embodiments, the partial wall is about two to three feet wide and about five feet tall. However, it should be understood that the partial wall may be any width and height depending on the application. A base of the partial wall is coupled to at least three wheels, and in particular embodiments to four wheels. An enclosure is coupled to one of the front and back surface of the partial wall. In various embodiments, the enclosure is formed from a first portion that is mounted to the partial wall and a second portion that is releasably coupled to the first portion. In various embodiments, the second enclosure portion is connected on a first side by hinges to the first enclosure portion and is secured on a second side to the first enclosure portion by a lock. In some embodiments, the enclosure may be formed from a metal mesh to allow for air circulation through the enclosure. In particular embodiments, one or more fans may be mounted in the enclosure to promote air circulation throughout the enclosure.

The mobile office communication system also contains various electronic components that allow the user to setup mobile offices in any location. For example, an integrated services router and a security appliance are operatively coupled to one another and mounted in the enclosure. Furthermore, the system may also provide an indoor and outdoor wireless access point that are operatively coupled to the security appliance. The integrated services router may be operatively coupled to (1) one or more analog devices (e.g., fax machine, credit card processor, etc.) using an analog punch-down block, (2) one or more VoIP phones and computers via a switch, (3) a 4G/LTE wireless or 3^{rd} party DSL/cable failover internet connection via the security appliance and switch and (4) an incumbent local exchange carrier.

The mobile communication system allows the user to deploy multiple people to a remote site where digital and analog communication devices can be quickly deployed in the field to support the people. The system also allows the remote office to run its own secure local area network and wireless local area network without having to integrate into a third party network. For example, when a group of auditors go on-site to a client to perform the year end audit, the auditors may deploy the mobile communications system at the client site, which would provide telephone, computer and network communication between the auditors and their home office. These services can be provided without having to connect through the client's computer network.

### Exemplary Technical Platforms

As will be appreciated by one skilled in the relevant field, the present systems and methods may be, for example, embodied as a computer system or a computer system and a method. Accordingly, various embodiments may be entirely hardware or a combination of hardware and software. Any suitable computer readable storage medium may be utilized including, for example, hard disks, compact disks, DVDs, optical storage devices, and/or magnetic storage devices.

### Example System Overview

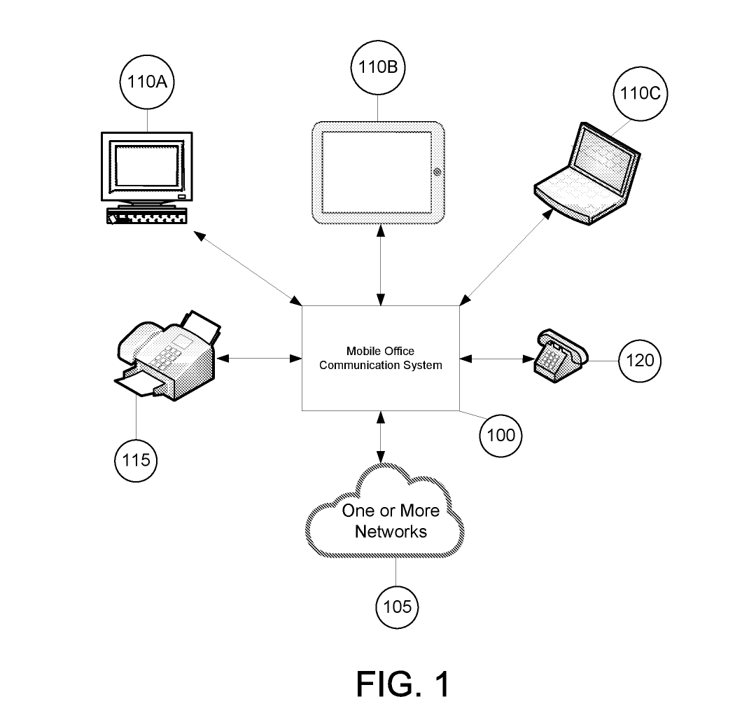

FIG. 1 is a block diagram of a mobile office communication system 100 according to a particular embodiment. As may be understood from this figure, the mobile office communication system 100 includes One or More Networks 105, One or More Computing Devices 110a, 110b, 110c (e.g., such as a laptop computer, a personal computer, a tablet, a smartphone, etc.), facsimile 115, and telephone 120. In particular embodiments, the Mobile Office Communication System 100 facilitates communication between the One or More Remote Computing Devices 110a, 110b, 110c, the facsimile 115, the telephone 120, and the One or More Networks 105.

The One or More Networks 105 may include any of a variety of types of wired or wireless computer networks such as the Internet, a private intranet, a mesh network, a public switch telephone network (PSTN), or any other type of network (e.g., a network that uses Bluetooth or near field communications to facilitate communication between computing devices). The communication link between the One or More Computing Devices 110a, 110b, 110c and the Mobile Office Communication System 100 may be, for example, implemented via a Local Area Network (LAN).

In particular embodiments, the Mobile Office Communication System 100 may be connected (e.g., networked) to other computing devices in a LAN, an intranet, an extranet, and/or the Internet as shown in FIG. 1. As noted above, the Mobile Office Communication System 100 may operate in the capacity of a server in a client-server network environment, or as a peer computing device in a peer-to-peer (or distributed) network environment. The Mobile Office Communication System 100 may comprise a desktop personal computing device (PC), a tablet PC, a set-top box (STB), a network router, a switch or bridge, or any other computing device capable of executing a set of instructions (sequential or otherwise) that specify actions to be taken by that computing device. Further, while only a single computing device is illustrated, the term “computing device” shall also be interpreted to include any collection of computing devices that individually or jointly execute a set (or multiple sets) of instructions to perform any one or more of the methodologies discussed herein.

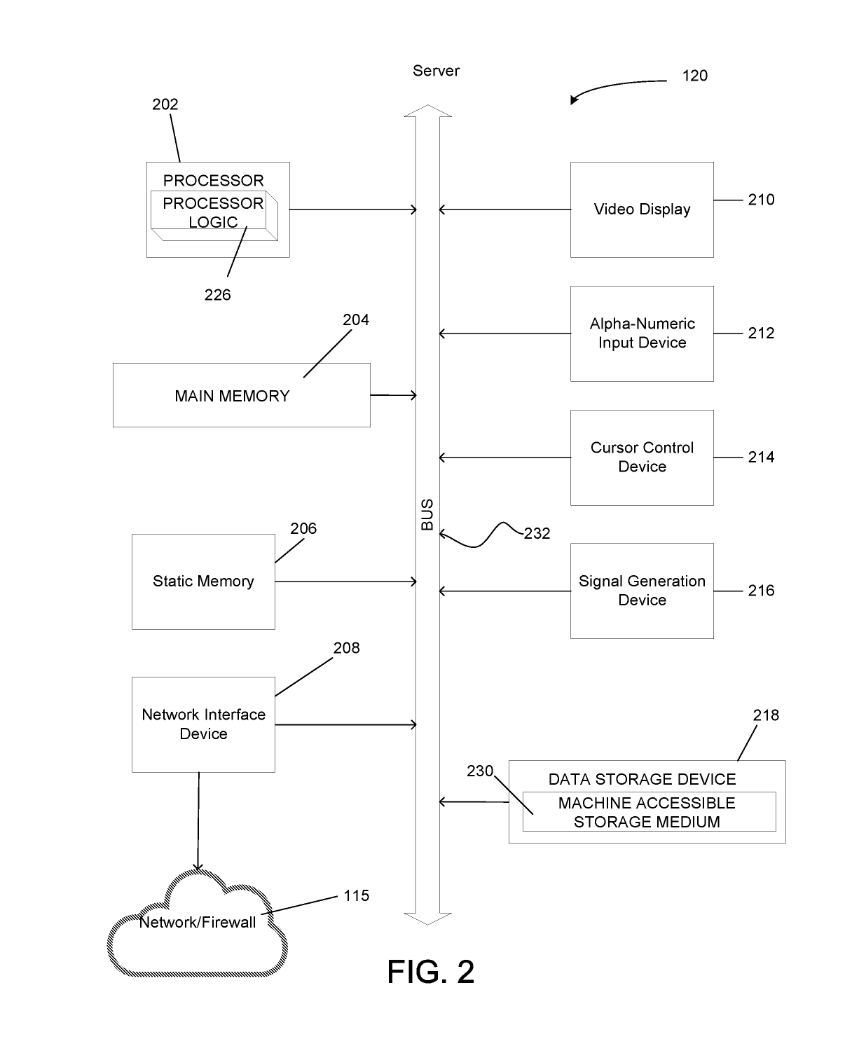

As may be understood from FIG. 2, an exemplary Mobile Office Communication System 100 includes a processing device 202, a main memory 204 (e.g., read-only memory (ROM), flash memory, dynamic random access memory (DRAM) such as synchronous DRAM (SDRAM) or Rambus DRAM (RDRAM), etc.), a static memory 206 (e.g., flash memory, static random access memory (SRAM), etc.), and a data storage device 218, which communicate with each other via a bus 232.

The processing device 202 represents one or more general-purpose or specific processing devices such as a microprocessor, a central processing unit (CPU), or the like. More particularly, the processing device 202 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. The processing device 202 may also be one or more special-purpose processing devices such as an application specific integrated circuit (ASIC), a field programmable gate array (FPGA), a digital signal processor (DSP), network processor, or the like. The processing device 202 may be configured to execute processing logic 226 for performing various operations and steps discussed herein.

The Mobile Office Communication System 100 may further include a network interface device 208. The Mobile Office Communication System 100 may also include a video display unit 210 (e.g., a liquid crystal display (LCD) or a cathode ray tube (CRT)), an alphanumeric input device 212 (e.g., a keyboard), a cursor control device 214 (e.g., a mouse), and a signal generation device 216 (e.g., a speaker).

The data storage device 218 may include a non-transitory computing device-accessible storage medium 230 (also known as a non-transitory computing device-readable storage medium or a non-transitory computing device-readable medium) on which is stored one or more sets of instructions embodying any one or more of the methodologies or functions described herein. The instructions may also reside, completely or at least partially, within the main memory 204 and/or within the processing device 202 during execution thereof by the Mobile Office Communication System 100—the main memory 204 and the processing device 202 also constituting computing device-accessible storage media. The instructions may further be transmitted or received over a network 115 via a network interface device 208.

While the computing device-accessible storage medium 230 is shown in an exemplary embodiment to be a single medium, the term “computing device-accessible storage medium” should be understood to include a single medium or multiple media (e.g., a centralized or distributed database, and/or associated caches and servers) that store the one or more sets of instructions. The term “computing device-accessible storage medium” should also be understood to include any medium that is capable of storing, encoding, or carrying a set of instructions for execution by the computing device and that cases the computing device to include any one or more of the methodologies of the present invention. The term “computing device-accessible storage medium” should accordingly be understood to include, but not be limited to, solid-state memories, optical and magnetic media, etc.

### Example Mobile Wall System Structure

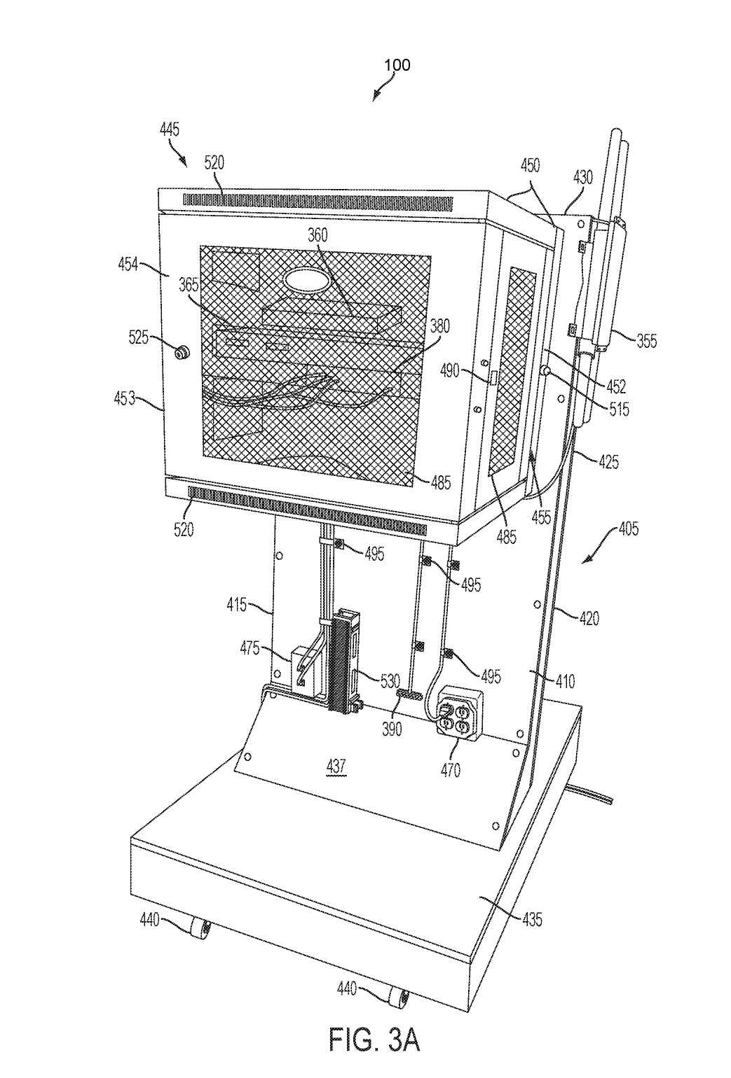

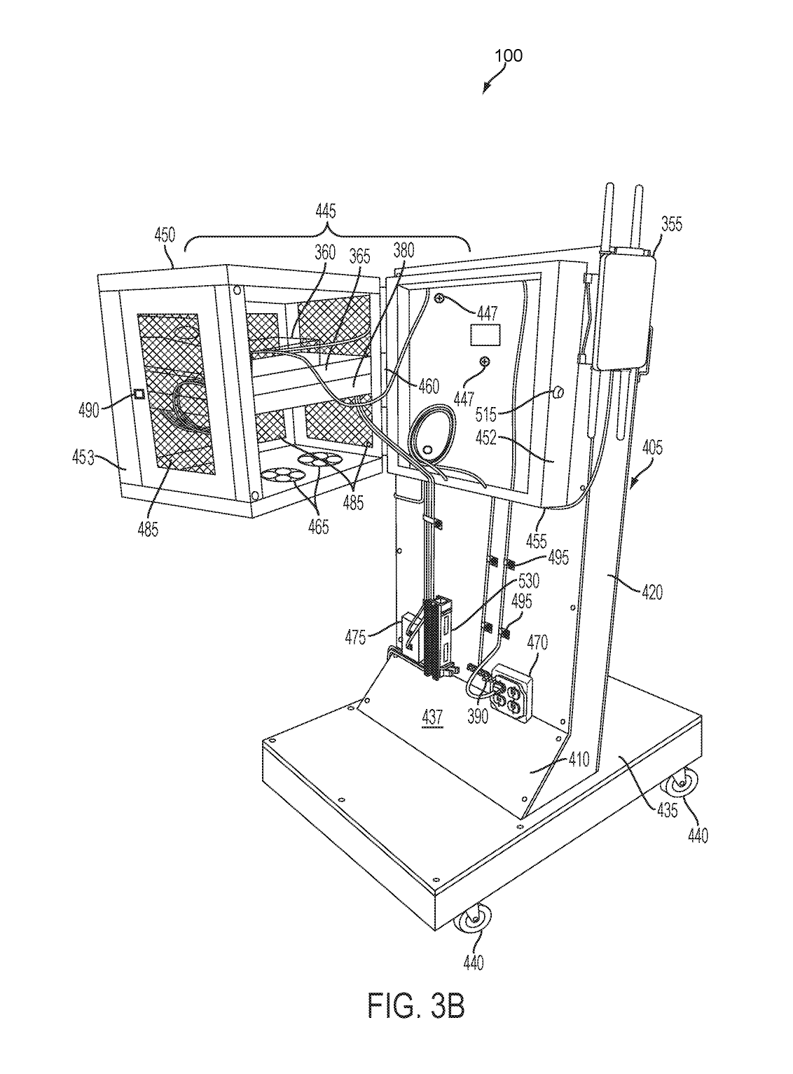

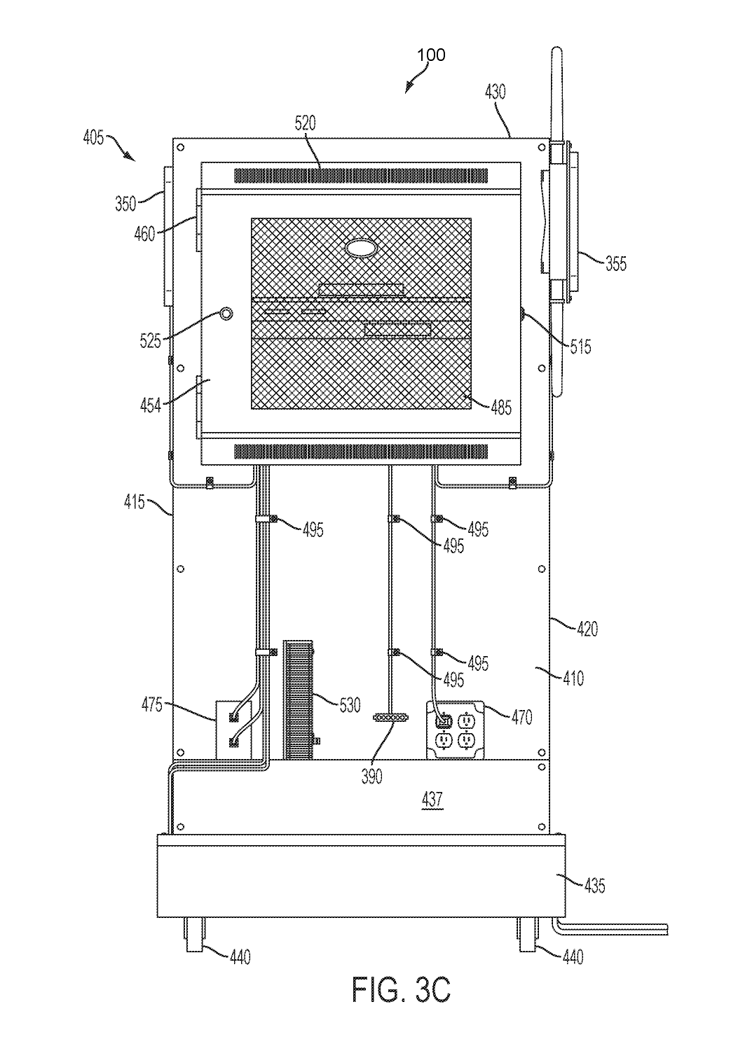

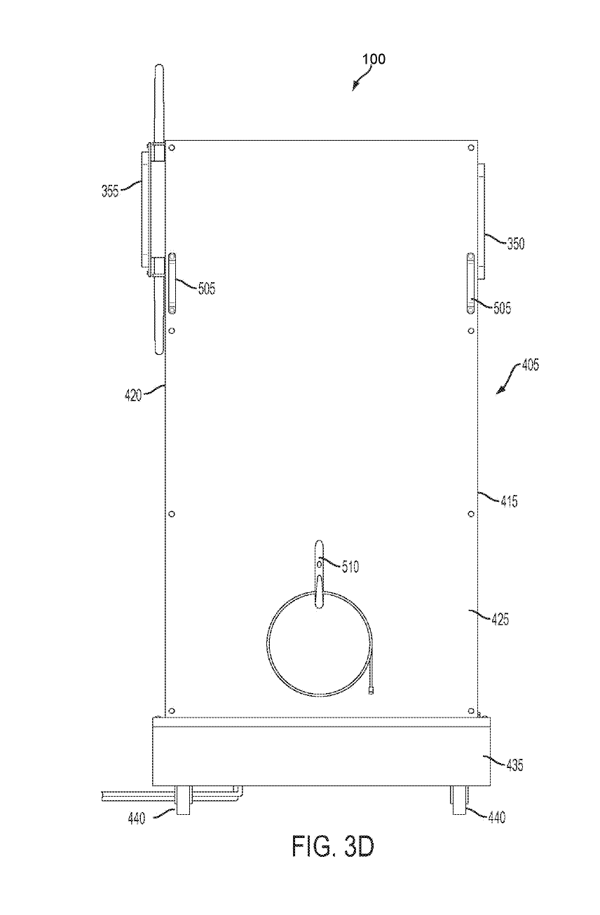

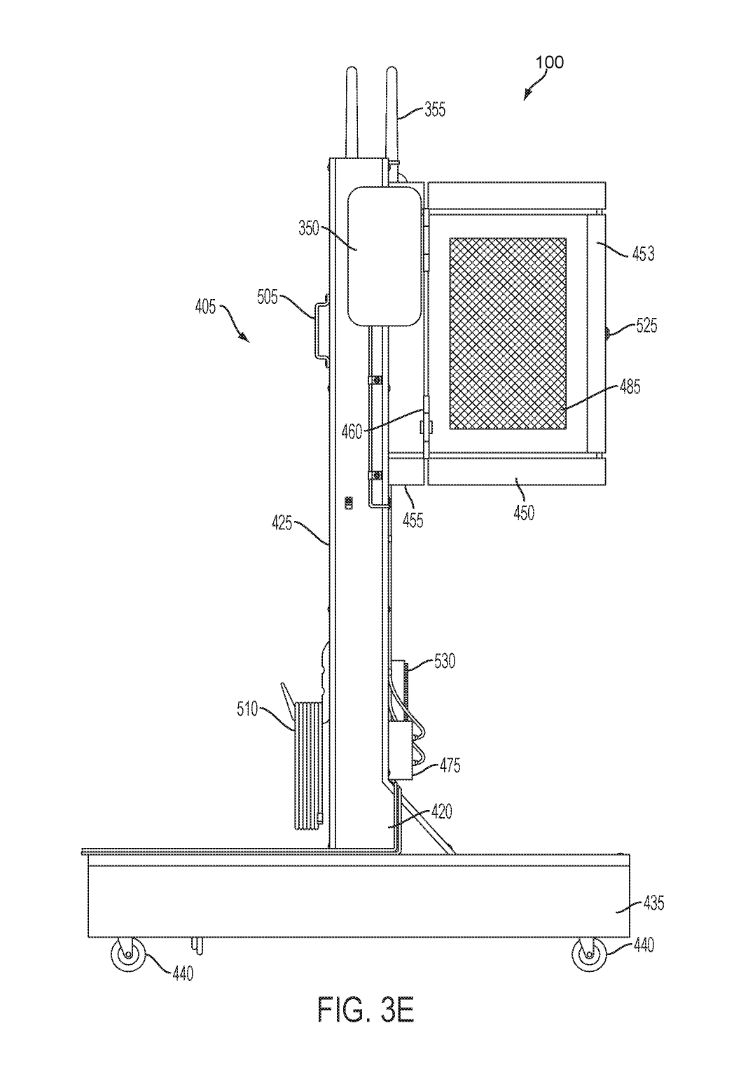

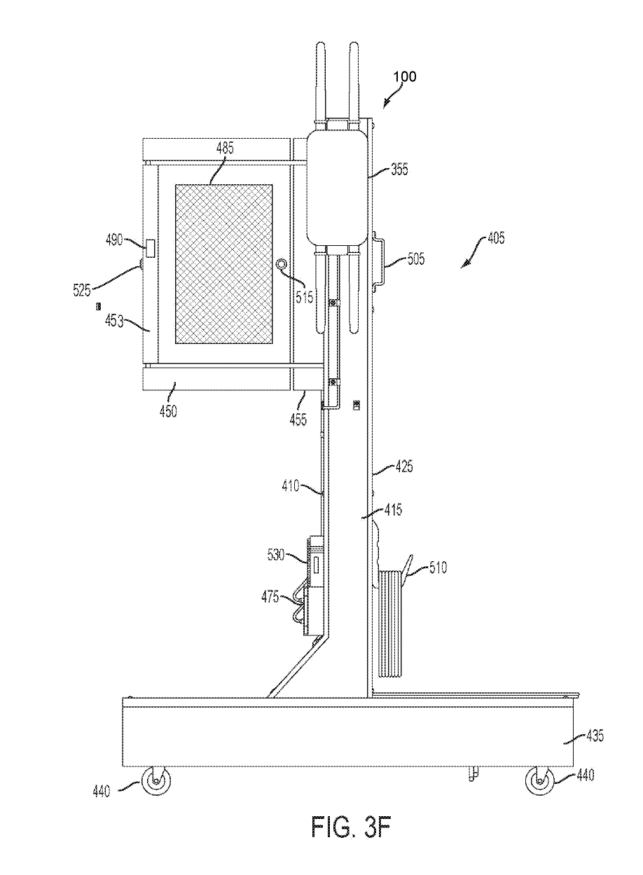

FIGS. 3A-3F depict an exemplary Mobile Office Communication System 100 that a user may experience when implementing the system to access an external network. FIG. 3A depicts a left front perspective view of the mobile office communication system 100. As may be understood from this figure, a partial mobile wall 405 comprises a front wall 410, a right sidewall 415, a left sidewall 420, a back wall 425, a top wall 430 and a base 435. In various embodiments, the base 435 is coupled to a plurality of wheels 440. In some embodiments, the partial mobile wall 405 may be formed from any suitable material (e.g., a polymer, wood composite, drywall, etc.). In various embodiments the partial mobile wall 405 is about 2-3 feet wide and approximately 5 feet tall. In other embodiments the partial mobile wall 405 may be any width and any height based on the application of the mobile communication system. In some embodiments, the partial mobile wall 405 may be hollow to allow the user to route the cabling through the wall as opposed to mounting the cables on the surface of the wall.

Still referring to FIG. 3A and also referring to FIG. 3B, an enclosure 445 is coupled to the front surface 410 of the partial mobile wall 405. The enclosure 445 may be coupled to the front surface 410 using screws, bolts, rivets, or any other suitable fasteners 447. The enclosure 445 is formed from an enclosure first portion 450, an enclosure second portion 455 that is releasably secured to the enclosure first portion 450 by a hinge 460 (FIG. 3B) and a first locking mechanism 515 located on the left surface 452 of the enclosure second portion 455, and an enclosure third portion (e.g., a door) 453 that is releasably secured to the enclosure second portion 455 by a hinge (not shown) on a first side and releasably secured by a second locking mechanism 525 (FIG. 3A) located on a front surface 454 of the enclosure third portion 453 at a second side such that when unlocked the enclosure third portion 453 can be opened to access the electrical equipment stored in the enclosure.

Mounted on the lower portion of the front surface 410 are an electrical outlet 470, network wall plate 475 and a ground mounting block 390 (FIG. 3A). Affixed to the left wall surface 420 is an outdoor 802.11n access point 355. Additional features of the mobile office communication system include wheels 440 affixed to the base 435, as well as enclosure ventilation gratings 485. Referring in particular to FIG. 3B, the enclosure first portion 450 is configured to house various electrical components such as an integrated services router 380, a cloud managed security appliance 360, a switch 365, and exhaust fans 465.

In various embodiments, the electrical components may be placed on shelves formed in the enclosure, and in other embodiments, the electrical components may be rack mounted in the enclosure. In some embodiments, the enclosure 445 may additionally house one or more redundant networking devices (e.g. additional routers, gateways, switches, hub, etc.) in addition to the aforementioned networking devices. In still other embodiments, the base 435 may be hollow and hinged such that a top surface 437 of the base 435 may be opened in the vertical plane to supply additional storage. As may be further understood from this figure, cabling from the various networking components may be secured to at least the front surface 410 by a securing means 495 (e.g. cable tie downs, cable tracks, lashing ties, etc.).

FIG. 3C depicts a front view of the mobile office communication system 100. As may be further understood from this Figure, affixed to the right side wall 415 of the mobile office communication system 100 is an indoor 802.11n access point 350. Additionally, one or more louvered vents 520 may be further incorporated into at least a portion of at least one surface 454 of the enclosure first portion 450 to facilitate ventilation, air flow, and dust minimization. The louvered vents 520 may be of any height, width, distance between vents, and angle relative to the plane in which the vents lie as may be suitable for the particular application.

FIG. 3D depicts a rear view and FIG. 3E depicts a right side view of the mobile office communication system 100. As may be understood from these figures, the back wall 425 supports two handles 505 that may be utilized to push and steer the mobile office communication system 100. Moreover, a hook 510 is provided to store additional network cables, extensions cords, and the like. In various embodiments, the back wall 425 may additionally have securing means (e.g. brackets, hooks, etc.) (not shown) such that the mobile office communication system may be secured to a transporting means (e.g. handtruck) or to a wall for additional security and/or stability during transport or when temporarily installed at a work location. As shown in FIG. 3E, the enclosure first portion 450 and the enclosure second portion 455 are operatively coupled to one another and shown in a closed position. The hinge mechanism 460 enables a pivotal coupling between the enclosure first portion 450 and the enclosure second portion 455, which allows the enclosure first portion to pivot with respect to the enclosure second portion. As discussed herein, the wheels 440 are affixed to the base 435 to provide mobility to the mobile office communication system 100.

FIG. 3F depicts a left side view of the mobile office communication system with the enclosure first portion 450 and the enclosure second portion 455 operatively coupled to one another. Additionally, the first locking mechanism, 515 operatively couples the enclosure first portion 450 to the enclosure second portion 455 such that the enclosure 445 securely houses the various electronic components. As may be understood from this figure, the outdoor 802.11n access point 355 is affixed to the left side wall 415 via securing means (screws, bolts, zip ties, etc.).

### Example System Architecture

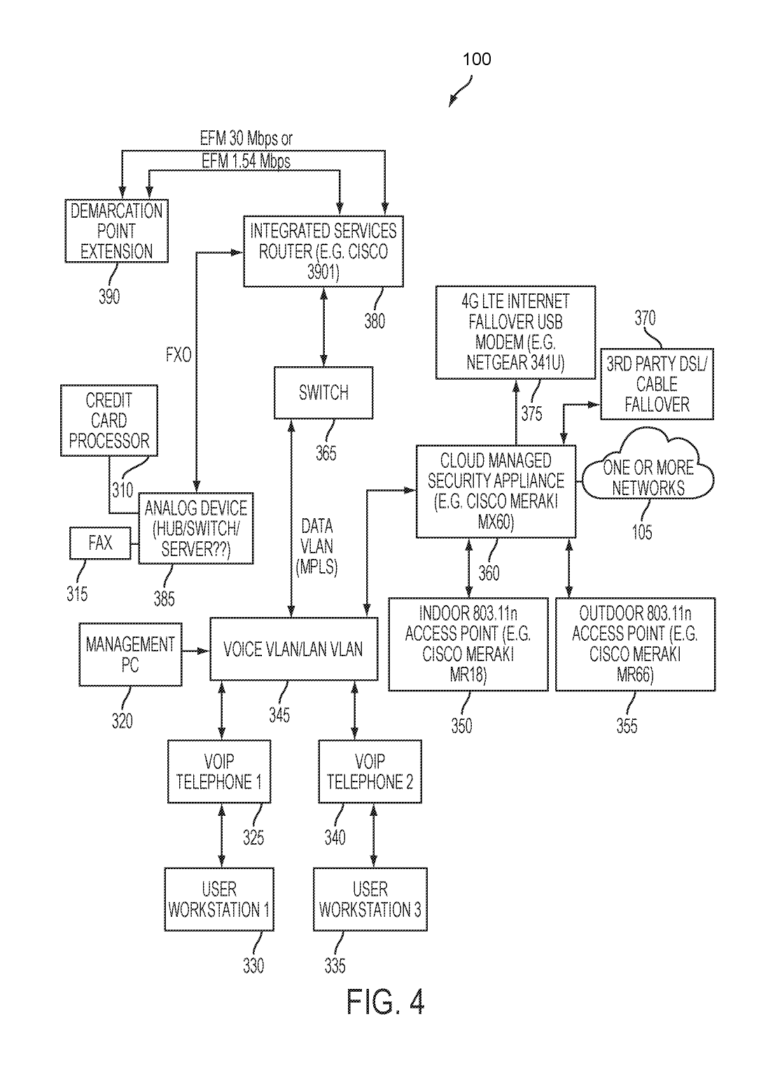

As may be understood from FIG. 4, in various embodiments, the Mobile Office

Communication System 100 may be composed of a variety of network appliances, communications appliances, and the interconnected components and connection apparatuses as shown in the figure. In particular embodiments, the Mobile Office Communications System 100 may comprise the One or More Networks 105 connected to a Cloud Managed Security Appliance 360 via generally accepted means (e.g. a network cable). The Cloud Managed Security Appliance (e.g. Cisco Meraki MX60, etc.) 360 is configured to provide a secure connection between an external network via integrated security means (e.g. a firewall, other port configuration means) and the internal network composed of the various components of the Mobile Office Communication System 100. The Cloud Managed Security Appliance 360 may be further configured to control network traffic routing or other connectivity optimization methods. As may be further understood from FIG. 3, in various embodiments, the Cloud Managed Security Appliance 360 is further connected via generally accepted means to any combination of an Indoor 803.11n Access Point 350 (e.g. Cisco Meraki MR18, etc.) an Outdoor 803.11n Access Point 355 (e.g. Cisco Meraki MR66, etc.), a Voice VLAN/LAN VLAN 345, a 3^{rd} Party DSL/Cable Failover 370, and a 4G LTE Internet Failover USB Modem (e.g. Netgear 341U, etc.) 375.

The Access Points 350,355 are configured to provide a secure wireless connection to authenticated computing devices (e.g. a laptop, a desktop with a wireless network card, a smartphone, a tablet, a PDA, or other similar interne capable devices). Additionally, the 3^{rd} Party DSL/Cable Failover 370 and the 4G LTE Internet Failover USB Modem 375 are further configured to provide a redundant connection to external networks should the One or More Networks 105 experience outages or other connectivity issues. In particular embodiments, the Voice VLAN/LAN VLAN 345 is configured to provide connectivity to the VOIP telephones 325,340, which in turn provide connectivity to the User Workstations 330, 335. The Voice VLAN/LAN VLAN may further provide connectivity to a Management PC 320 via a Data VLAN (MPLS) connection to a Switch 365.

In particular embodiments, the Switch 365 is operatively connected to an Integrated Services Router 380 (e.g. Cisco 3901, etc.). The Integrated Services Router 380 in turn provides connectivity to a Demarcation Point Extension 390 via an Ethernet in the first mile (EFM) 3.0 or 1.54 Mbps T1 connection, and a foreign exchange office (FXO) interface connectivity to an Analog Device 385. The Analog Device 385 will in turn provide connectivity to any number of analog devices, such as a Credit Card Processor 310 or a Fax 315.

### Alternate Embodiments

In various embodiments, the Mobile Office Communication System 100 may be composed of particular network appliances, communication devices, or connectivity features not discussed above, or in other embodiments, the Mobile Office Communication System 100 may omit one or more of the devices discussed above. While example network appliances and communication devices are referenced in this Application, in no way is this meant to limit the claimed invention to the specific configuration discussed herein.

For example, some of the network appliances and communication devices referenced in this application are discussed based on certain embodiments of the system. Similar appliances exist to provide substantially similar functionality but greater scalability to the end-user (e.g. provide support for a greater number of contemporaneous users). In various embodiments, the system may be further configured to utilize a gateway, router, cloud managed security appliance, punchdown blocks, etc. to support a larger number of end-users contemporaneously. In particular embodiments, additional cable/DSL modems and 4G wireless modems may be necessary to support a greater number of end-users at a reasonable and useable connection speed. In particular embodiments, the system may additionally be configured to support additional storage capability within the base 435, enclosure 445, or within the compartment formed between the front surface 410, right side wall 415, left side wall 420, back surface 425, top 430, and base 435. Such an embodiment may additionally include hinges or similar operatively coupling means on at least one of the meeting edges of the back surface 425 and either the left side wall 420 or the right side wall 415 to provide quick interior access, and a locking mechanism to provide security.

In various embodiments, the mobile office communication system 100, may further comprise a hollow cavity between the space formed by the front surface 410, right side wall 415, left side wall 420, back surface 425, top 430, and base 435. This space, may be utilized to route cables from the components contained within the enclosure 445 to an analog punch-down block 530, network wall plate 475, or other connector receptacle. The cables may be secured to the partial wall 405 with conventional means (e.g. cable tie downs) 495. Additionally, the wheels 440 may be further configured to operatively lock/unlock such that the mobile office communication system can be freely moved to a location, but once positioned within the location the wheels may be locked in place to further secure the system.

In some other embodiments, the mobile office communication system 100, may further comprise one or more uninterrupted power supplies (UPSs), a Random Array Independent Disk Server (RAID server), and an administrator computer terminal located behind the cloud managed server/firewall 360. The UPS may be connected in series between the power source and the mobile office communication system 100 such that it is maintained with a charging current and in the event of an electrical outage will provide battery backup to the electrical components of the mobile office communication system 100. Additionally, the RAID server may be configured to support a redundant backup of the user's information, such that in the event of network connectivity issues or general disk failure in a user's computer loss of information is minimized.

In some other embodiments, additional network signal amplification means may be utilized to aid network connectivity. These means may comprise a signal repeater, which may be stored in the base 435 or front enclosure portion 450, such that the signal repeater may be utilized and positioned within a client's office to overcome signal loss due to structural materials through which the signal must travel or interference from other signals. The system may further comprise a bi-directional signal amplifier, which may be utilized similarly to the signal repeater, to strengthen the broadcasting signal within a client's work space.

### Illustrative Examples

Auditors

In a particular example, the Mobile Office Communication System 100 may be implemented in an audit setting to provide secure remote access to the auditing firms' internal servers while allowing the auditors to remain on-site at the audit location without the need to rely on any existing network architecture and connectivity. In a particular application in the audit setting, the Mobile Office Communication System is able to provide external network access on-site via a wired connection or wireless access points, without the need to configure the personal computer or communications device of every individual. By utilizing the Mobile Office Communication System 100, the network connectivity authentication process and security settings can be maintained by the auditors' network administrators without the need for the on-site network administrators to alter internal security or authentication processes. Further, by providing redundancies, the system is able to provide external network access in the event of a temporary internet outage or other connectivity issues. Lastly, by maintaining one central connection to the external network, the system is configured to accommodate more individuals within a workspace than the existing network connectivity may be configured to provide.

### CONCLUSION

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for the purposes of limitation.

What is claimed is:

1. A mobile office communication system comprising:
a. a portable wall comprising:
i. a front surface,
ii. a first side surface,
iii. a second side surface, and
iv. a back surface;
b. an enclosure mounted to one of the front surface and the back surface, the enclosure comprising:
i. a first enclosure portion mounted to the one of the front surface and the back surface, and
ii. a second enclosure portion that is releasably coupled to the first enclosure portion;
c. an electrical connector mounted to the portable wall;
d. a security appliance that is received in the enclosure;
e. an integrated services router that is received in the enclosure; and
f. at least one of a 4G wireless modem and a cable modem,
wherein:
the electrical connector is configured to operatively couple to a power source and to provide at least one electrical outlet on the mobile office communication system, and
the security appliance, the integrated services router and the at least one of the 4G wireless modem and the cable modem are operatively coupled to one another and to the electrical connector.

2. The mobile office of claim 1, wherein the portable wall comprises a plurality of wheels operatively coupled to the portable wall that allows the portable wall to roll.

3. The mobile office of claim 2, further comprising a base operatively coupled to the portable wall, wherein the wheels are coupled to the base.

4. The mobile office of claim 3, wherein the base contains a storage compartment therein.

5. The mobile office of claim 1, wherein the second enclosure portion is configured to lock to the first enclosure portion to secure the security appliance and the integrated services router inside the enclosure.

6. The mobile office of claim 5, wherein the second enclosure portion further comprises:
a. a second enclosure portion main body; and
b. a second enclosure portion door,
wherein the second enclosure portion door is pivotally coupled to the second enclosure portion main body at a first side and is releasably secured to the second enclosure portion main body at an opposite second side by a lock.

7. The mobile office of claim 5, further comprising a server operatively coupled to the security appliance and the integrated services router.

8. The mobile office of claim 1, further comprising:
a. a plurality of digital phone operatively coupled to the integrated services router and the security appliance;
b. at least one analog device operatively coupled to the integrates services router; and
c. at least one Wi-Fi access point operatively coupled to the security appliance.

9. The mobile office of claim 1, further comprising both a 4G wireless modem and a cable modem.

10. The mobile office of claim 1, wherein the portable wall is hollow thereby allowing cables to be routed through the hollow area of the portable wall.

11. A method of providing a mobile communication system for use with mobile offices comprising:
a. providing a portable communication system comprising:
i. a wall having wheels,
ii. an equipment enclosure,
iii. an integrated services router that is configured to operatively couple to a network,
iv. a security appliance that is configured to operatively couple to a wireless modem, and
v. a power connector that is configured to connect to a power source and to provide power to the integrated services router and the security appliance;
b. operatively coupling the integrated services router to the security appliance; and
c. operatively coupling the integrated services router and the security appliance to the power connector.

12. The method of claim 11, wherein the enclosure is configured to securely store the integrated serviced router and a server therein.

13. The method of claim 11, further comprising:
a. providing one or more of a wireless modem, a cable modem and a DSL modem;
b. operatively coupling the one or more of a wireless modem, a cable modem and a DSL modem to the security appliance.

14. The method of claim 11, wherein the wall is hollow and is configured to allow cabling to be routed through the wall.

15. The method of claim 11, wherein the wall is between one and three feet wide and between two and five feet tall.

16. The method of claim 15, wherein the wall is approximately two feet wide and between two and four feet tall.

17. A portable communication system comprising:
a. a mobile wall;
b. a means for securing one or more analog and/or digital communication devices to the mobile wall;
c. a means for providing a secure local area network that is configured to allow at least one digital device to connect to the local area network;
d. a means for allowing at least one analog device to connect to the local area network; and
e. a means for operatively connecting the local area network to the internet,
wherein:
the electrical connector is configured to operatively couple to a power source and to provide power to the means of providing a secure local area network.

18. The portable communication system of claim 17, wherein the means for securing one or more analog and/or digital communication devices to the mobile wall further comprises a three part enclosure that comprises:
a. a first portion that is secured to the mobile wall;
b. a second portion that is pivotally coupled to the first portion on a first side and releasably coupled to the first portion on a second side; and
c. a third portion that is pivotally coupled to the second portion on a first side and releasably coupled to the second portion on a second side.

19. The portable communication system of claim 18, wherein the means for securing one or more analog and/or digital communication devices to the mobile wall further comprises a racking system for mounting one or more pieces of electronic equipment in the enclosure.

20. The portable communication system of claim 17, wherein the mobile wall further comprises wheels for moving the mobile wall from a first location to a second location.
